(19) United States
(12) Patent Application Publication
(10) Pub. No.: US 2006/0011470 A1
(43) Pub. Date: Jan. 19, 2006

(54) Sputtering magnetron control devices

(76) Inventors: Gareth P. Hatch, East Dundee, IL (US); Christopher A. Ras, Arlington Heights, IL (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/182,596

(22) Filed: Jul. 14, 2005

Related U.S. Application Data
(60) Provisional application No. 60/588,691, filed on Jul. 16, 2004.

(51) Int. Cl. C23C 14/00; C23C 14/32

(52) U.S. Cl. 204/192.12; 204/298.2; 204/298.22

(57) ABSTRACT

Embodiments relate to manipulating and controlling the magnetic field profile of a magnetron within a sputtering system dynamically (i.e., in real time), to most effectively utilize the target material as required by any stage of its erosion and to sputter deposit films with a desired profile or characteristics. In particular, embodiments relate to dynamic positional and rotational control of the magnetron or individual elements of the magnetron to alter the magnetic field profile of the magnetron during deposition.

### CLAIM OF PRIORITY

This application is related to, and hereby claims the benefit of, provisional application No. 60/588,691 filed Jul. 16, 2004.

### FIELD

Embodiments of the invention relate to sputtering magnetrons and more specifically to the positional and rotational control of sputtering magnetrons.

### BACKGROUND

The primary use for sputtering magnetrons is to sputter material from a target to deposit the target material on a deposition substrate. Fundamentally speaking, sputter deposition stems from a direct current glow discharge (i.e., plasma discharge) between an anode and a cathode in a vacuum. A neon sign is a simple example of such a direct current glow discharge. For sputtering, the cathode is a composed of a target material for which an incident ion knocks loose a target material atom. The target material atom then sticks to whatever surface it strikes. Sputtering a uniform layer of target material on a substrate requires a high level of target material atom scattering. However, such heightened scattering mandates a higher rate of target material consumption and requires frequent deposition chamber cleaning.

In particular, sputtering magnetrons are used in a number of industries to deposit thin films of material onto desired substrates. Much of the work in optimizing the performance and efficiency of such systems has focused on the profile of the magnetic field generated by the magnetron. In general, the profile of the magnetic field generated by the magnetron is tailored primarily to extend the useful life of the target material and to optimize the profile of the deposited film. Typically such magnetrons are either static or rotate in the plane of the magnetron (i.e., parallel to the surface of the target and substrate).

### BRIEF DESCRIPTION OF THE DRAWINGS

FIG. 1: illustration of a schematic of a sputtering magnetron gun of an embodiment

FIG. 2: illustration of a schematic of a controller of an embodiment to control the sputtering magnetron gun of an embodiment

FIG. 3: illustration of a schematic of a controller and sputtering magnetron guns in combination as a station of an embodiment

FIG. 4a: illustration of a schematic of the sputtering magnetron gun of an embodiment in a first position

FIG. 4b: illustration of a schematic of the sputtering magnetron gun of an embodiment in a second position

FIG. 5: illustration of the controller of an embodiment controlling multiple sputtering magnetron stations

FIG. 6: illustration of a process of an embodiment

### DETAILED DESCRIPTION

Embodiments of a rotating sputtering magnetron control system and method of operation thereof will be described. Reference will now be made in detail to a description of these embodiments as illustrated in the drawings. While the embodiments will be described in connection with these drawings, there is no intent to limit them to drawings disclosed herein. On the contrary, the intent is to cover all alternatives, modifications, and equivalents within the spirit and scope of the described embodiments as defined by the accompanying claims.

Simply stated, embodiments relate to manipulating and controlling the magnetic field profile of a magnetron within a sputtering system dynamically (i.e., in real time), to most effectively utilize the target material as required by any stage of its erosion and to sputter deposit films with a desired profile or characteristics. In particular, embodiments relate to dynamic positional and rotational control of the magnetron or individual elements of the magnetron to alter the magnetic field profile of the magnetron during deposition.

An embodiment encompasses a number of approaches to optimizing the magnetic field profile within both rotary and linear magnetron sputtering systems. For example, rotary magnetron systems generally comprise a circular or other shaped magnetron that is rotated about some axis in the plane of the magnetron at varying speeds. Linear magnetron systems generally comprise a static magnetron assembly that does not move. As the ideal magnetron magnetic field profile at the beginning of a deposition process (e.g., with a fully intact target) is not necessarily the same in the middle or end stages of target use (e.g., when a portion of the target has been eroded), the ability to adjust the magnetic field during the deposition may improve the overall efficiency of the sputtering magnetron during a deposition or multiple depositions and further improve the profile or characteristics of the sputter deposited film. Accordingly embodiments relate to the ability to change that magnetic field profile dynamically to better match the magnetron magnetic field profile, and resulting deposition efficiency, and deposited film characteristics, to any stage in the deposition process.

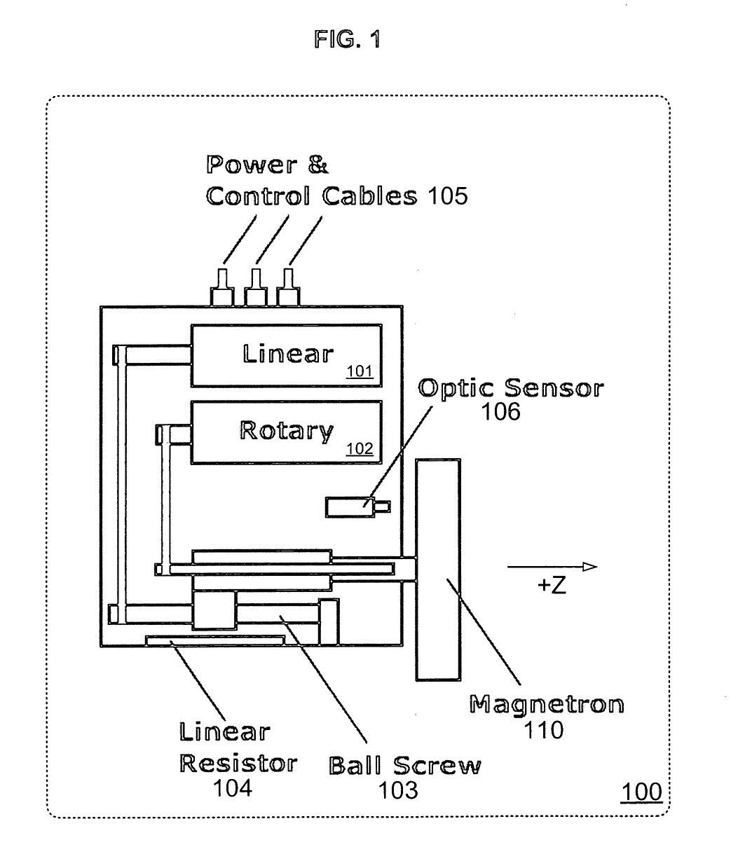

FIG. 1 illustrates of a schematic of a sputtering magnetron gun 100 of an embodiment including a linear motor 101, a rotary motor 102, a ball screw 103, a linear resistor 104, power and control cables 105, optic sensor 106, and magnetron 110. The magnetron 110 can be any magnet or arrangement of multiple magnets that generates a magnetic field density sufficient to sputter deposit a material. The rotary motor 101 coupled to the magnetron 110, for example through a shaft, rotates the magnetron. The linear motor 101 extends and retracts the magnetron 110 toward and away from a target and/or substrate (not illustrated). In an embodiment, the linear motor 101 extends and retracts the magnetron 110 by rotating a ball screw 103 coupled to, for example, the shaft and the magnetron 110. The linear resistor 104 verifies the position of the magnetron 110 along the illustrated z axis in addition to or in lieu of positional feedback from the linear motor 101. Similarly, optic sensor 106 verifies the rotation of the magnetron 110 about the z axis in addition to or in lieu of rotational feedback from the rotary motor 102.

It is to be understood that the linear motor 101 and the rotary motor 102 are referred to by the resulting motion of the magnetron 110, and not by the motor mechanism itself. It is intended that linear motor 101 encompass any device (mechanical, electromechanical, hydraulic, pneumatic, etc.) or combination of devices that causes the magnetron 110 to move linearly along the z axis as illustrated. Similarly, it is intended that rotary motor 102 encompass any device (mechanical, electromechanical, hydraulic, pneumatic, etc.) or combination of devices that causes the magnetron 110 to rotate. In an embodiment, the rotary motor 102 rotates the magnetron around the z axis.

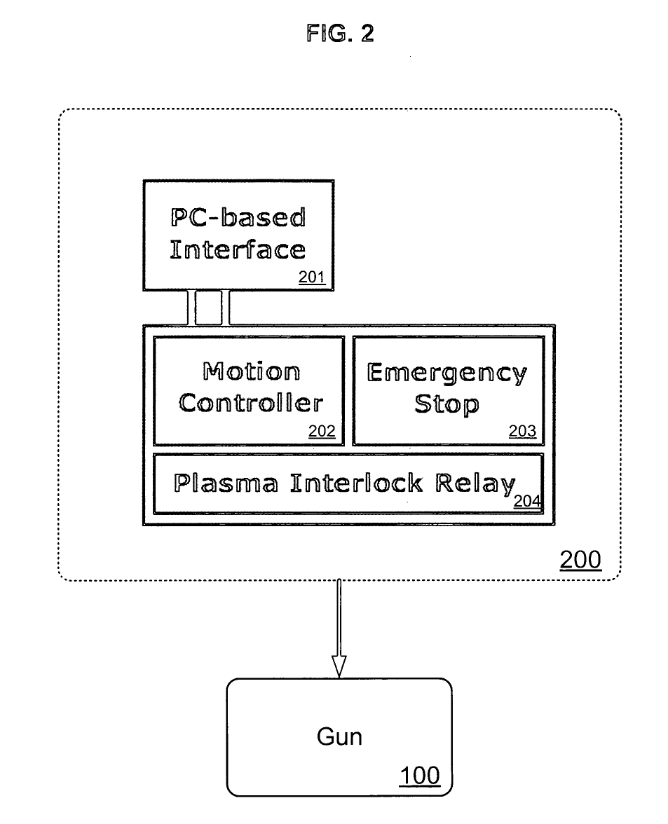

FIG. 2 illustrates a schematic of a controller 200 of an embodiment to control the sputtering magnetron gun 100. The controller 200 of an embodiment includes a PC-based interface 201 coupled to a motion controller 202, an emergency stop 203, and a plasma interlock relay 204. The controller 200 is further coupled to the sputtering magnetron gun 100 via at least a portion of the power and control cables 105. The motion controller, as will be explained more fully below, controls the rotational and linear motion of the magnetron 110 within the sputtering magnetron gun 100. The emergency stop 203 is a manual (e.g., initiated by an operator) or an automatic (e.g., initiated by operational parameters outside determined thresholds) safety mechanism that pauses or halts a sputter deposition process. Plasma interlock relay 204 similarly pauses or halts the sputter deposition process if conditions within or around the deposition chamber (e.g., vacuum, temperature of the target or substrate surface, power consumption or an indication of a short circuit) require that the process be interrupted.

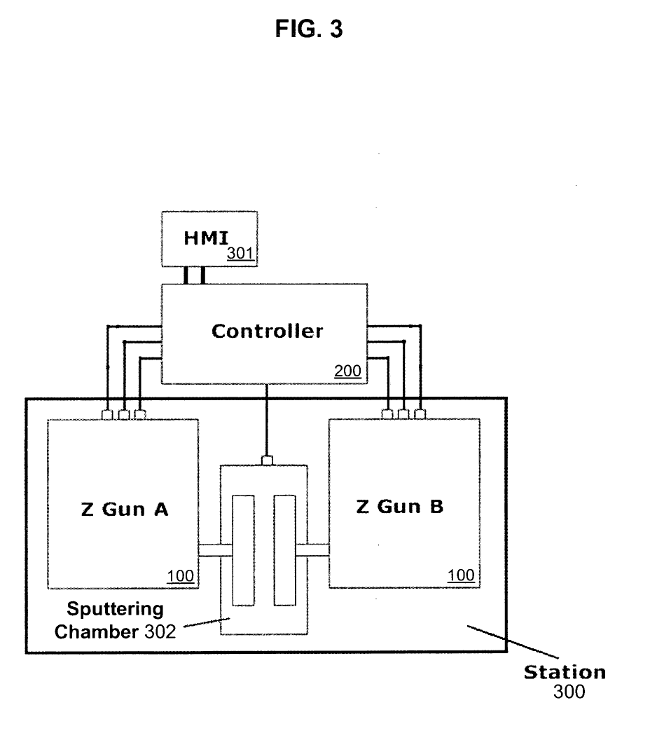

FIG. 3 illustrates a schematic of a controller 200 and two sputtering magnetron guns 100 in combination as a station 300 of an embodiment. Coupled the controller 200 is a human machine interface 301 so that an operator can interact with the controller. The two sputtering magnetron guns 100 in the station 300 are positioned in a sputtering chamber 302 such that their respective magnetrons 110 oppose each other approximately along the same z axis. Though not illustrated, it is to be understood that the sputtering chamber 302 further includes a target adjacent to each sputtering magnetron gun 100 and a substrate between the targets that, with such a dual sputtering magnetron gun 100 configuration, would deposit target material on both sides of the substrate. Further, while illustrated with two opposing sputtering magnetron guns 100, an embodiment to deposit target material on one side of the substrate would include only one sputtering magnetron gun.

In an alternate embodiment, the sputtering chamber 302 with two sputtering magnetron guns 100 and adjacent targets further includes two substrates such that, versus depositing a film on both sides of a single substrate as described above, the station 300 may be used to simultaneously sputter deposit a film on one side of each of the substrates.

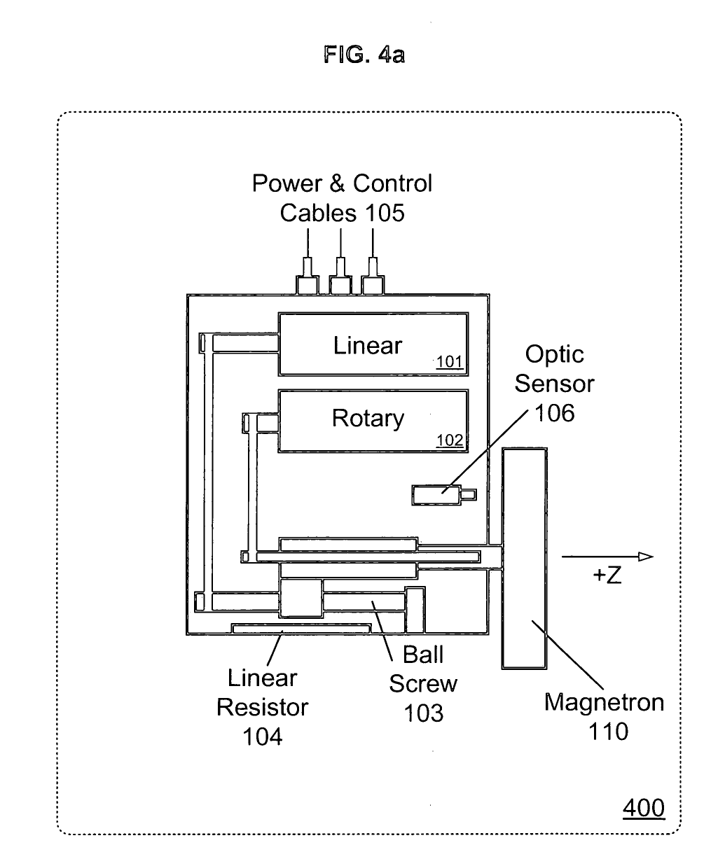

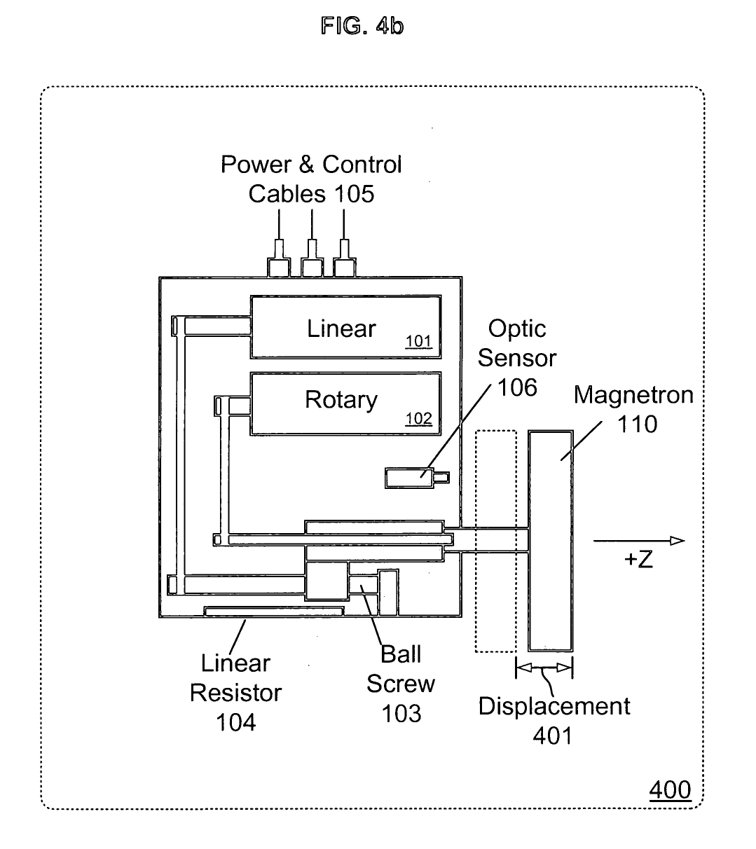

FIG. 4a illustrates a schematic of the sputtering magnetron gun 100 of an embodiment with the magnetron 10 in a first position. FIG. 4b illustrates a schematic of the sputtering magnetron gun 100 of an embodiment with the magnetron 110 in a second position. The displacement 401 along the z axis reflects, for example, instructions issued by the controller 200, via power and control cables 105, to control the linear motor to effect such linear magnetron 10 motion along the z axis.

The instructions from the controller 200 may further include instructions to control the rotary motor 102 to concurrently or alternatively effect magnetron 110 rotary motion. More specifically, for either embodiment including multiple magnetrons 110 (e.g., two opposing magnetrons 110), the controller 200, by controlling individual magnetron 110 motion and position along the z axis and rotation about the z axis may further control magnetron 110 phasing, or the orientation of one magnetron 110 to another magnetron 110 within a station. For example, one magnetron 110 may be rotationally offset (e.g., by some fraction of 360° rotation) from the other magnetron 110. Further, one magnetron 110 may rotate at a different speed than the other magnetron 110. The phasing may occur before, during, or after the sputter deposition or in increments thereof. The controller 200 can further control the phasing dynamically (i.e., in real time). For example, the controller 200 may alter the rotational offset and/or the rotational speed differential between the two magnetrons 110 during a deposition.

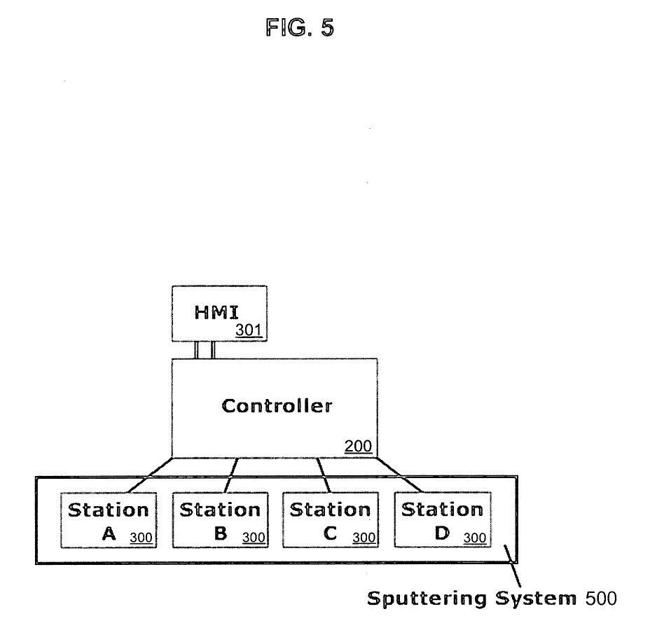

FIG. 5 illustrates a sputtering system 500 including a controller 200 of an embodiment with human interface 301 to control multiple sputtering magnetron stations 300. As noted above, each sputtering magnetron station 300 may include a single sputtering magnetron gun 100 to deposit target material on a single side of a substrate or may include two opposing sputtering magnetron guns 100 to deposit target material on two sides of the substrate or individual sides of multiple substrates. Further, each individual sputtering magnetron station 300 may be controlled independently from or differently than the other sputtering magnetron stations 300.

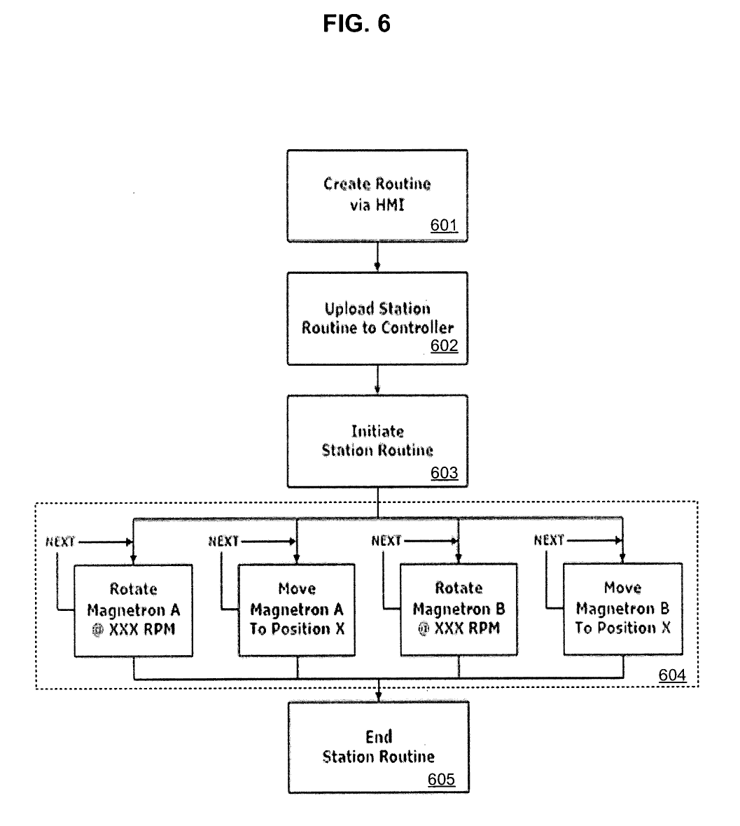

FIG. 6 illustrates a flow chart of a process of an embodiment to sputter deposit target material onto a substrate. At 601, an operator creates a deposition routine with the human machine interface. At 602, the deposition routine is uploaded to a controller (i.e., controller 200) or controllers. At 603, the deposition routine is initiated. At 604, the sputtering magnetron station or stations 300 perform the deposition routine. At 605, the routine ends once the sputter deposition has been completed.

More specifically, at 604, the sputtering magnetron station or stations 300, as controlled by a controller or controllers 200, perform the deposition routine that, for example, has been created by an operator. At 604 as illustrated, two magnetrons 110 are controlled for both their z axis position and for their rotational speed. It is to be understood that the magnetrons 110 could be part of the same sputtering magnetron station 300 or part of different sputtering magnetron stations 300. Further, though illustrated with two magnetrons 110, it is to be understood that the process would similarly apply to a single magnetron 110 or to many magnetrons 110 concurrently, sequentially, or a combination thereof.

Further for 604, and as has been introduced, there are different types of magnetrons and multiple forms of magnetron motion available to alter the magnetic field profile and resulting sputter deposition generated by the magnetron or magnetrons. The various magnetrons and motions represent myriad combinations that will be discussed in turn.

In an embodiment, a magnetron 110 is moved as a single unit. For example, the embodiment including a rotary magnetron would consist of a rotary magnetron mounted on a turntable. The RPMs, displacement of the turntable in the z axis (i.e., distance away from the target) and the duration for which the turntable moves or spins would be controlled, in any number of increments or steps, as desired by the operator. An operator may then change the magnetic field profile, in real time, in relation to the sputtering target during the sputtering process. The operator could also pre-program a set of deposition parameters to run the sputter deposition system to control the rotary magnetron (e.g, RPMs, z-axis displacement, and deposition duration) during operation with or without any additional operator input. An embodiment including a linear magnetron would have the same features as described above with reference to the rotary magnetron except that there would be no rotary motion. As such, the sputter deposition system would not control RPMs.

Further, an embodiment adds feedback control to either the rotary or linear magnetron described above. The embodiment would include placing protected probes or other measuring device within the sputtering system so that the magnetic field, temperature, thickness of target, and other parameters could be measured and fed back into the operating system of the sputtering system to make dynamic, real-time and/or pre-determined changes in the RPMs, z-axis displacement, and deposition duration, among other parameters, in response to the various probe or measurement device readings.

In an alternate embodiment, various portions of an individual magnetron (e.g., individual magnets of the magnetron magnet assembly) may be controlled individually. The portions could be displaced and rotated in any axis as desired. The movement of such portions would alter the overall magnetic field profile generated by the sputtering magnetron 110. The magnetron 110 portion positions could further be changed in real time in relation to the sputtering target during the sputtering process. The operator could also pre-program specific parameter combinations, and then run the system to control the magnetron 110 during operation. Controlling the individual portions of the magnetron 110 applies similarly to the rotary magnetron and the linear magnetron and may further utilize feedback control.

In addition to the embodiments outlined above, an additional embodiment would include electromagnet coils in addition to permanent magnets to provide additional real-time, dynamic control of the magnetic field profile of the sputtering magnetron system. Further, all of the above combinations could also apply to sputtering magnetron systems comprising only electromagnetic coils to generate the magnetic field. Such electromagnetic coils could be moved and/or rotated as described above with respect to sputtering magnetron systems including permanent magnets. Electromagnetic coils may also be included in combination sputtering magnetron systems where, in addition to either z-axis displacement or individual permanent magnet component displacements and orientations (and RPMs for rotary magnetrons), electromagnetic coils could be used to further increase, decrease or change the direction of magnetic field components within the combination sputtering magnetron system. Electromagnetic coils may be controlled by a variety of methods including controlling the current within the electromagnetic coils, altering the physical location of the coils, and altering the orientation of the coils in relation to the other permanent magnetic components.

Any of the above mentioned embodiments or combinations thereof may include a fully integrated computerized system to control all aspects of the mechanisms and processes used therein. Such a system would be capable of precisely controlling the magnetic field profile of any number of sputtering systems, simultaneously, through, for example, an interface that would allow an operator to either pre-program process parameters for semi-automatic sputtering system operation, allow the sputtering system to automatically develop process parameters algorithmically based on feedback from measuring devices within the sputtering systems as described above, or be completely manual. Individual process parameter adjustments, or combinations thereof, may be realized in real-time while the sputtering systems are operating.

One skilled in the art will recognize the elegance of the disclosed embodiments in that they improve the deposition efficiency and deposited film characteristics of a sputtering magnetron.

What is claimed is:

1. An apparatus comprising:
a magnetron station including a magnetron; and
a magnetron controller coupled to the magnetron station to dynamically control a magnetic field profile of the magnetron.

2. The apparatus of claim 1, the magnetron controller to further control a motion of the magnetron.

3. The apparatus of claim 2, the magnetron station further comprising:
a linear motor coupled to the magnetron to displace the magnetron along an axis.

4. The apparatus of claim 3, the magnetron station further comprising:
a rotary motor coupled to the magnetron to rotate the magnetron about the axis.

5. The apparatus of claim 4 further comprising:
an optic sensor to detect the rotational motion of the magnetron.

6. The apparatus of claim 4 further comprising:
a linear resistor to detect the location of the magnetron along the axis.

7. An apparatus comprising:
a magnetron station including a first magnetron and a second magnetron wherein the first magnetron and second magnetron are opposed; and
a magnetron controller coupled to the magnetron station to dynamically control a magnetic field profile of the first magnetron and the magnetic field profile of a second magnetron.

8. The apparatus of claim 7, the magnetron controller to further control a motion of the first magnetron and a motion of the second magnetron.

9. The apparatus of claim 8, the magnetron station further comprising:
a first linear motor coupled to the first magnetron to displace the first magnetron along an axis; and
a second linear motor coupled to the second magnetron to displace the second magnetron along the axis.

10. The apparatus of claim 8, the magnetron station further comprising:
a first rotary motor coupled to the first magnetron to rotate the first magnetron about the axis; and
a second rotary motor coupled to the second magnetron to rotate the second magnetron about the axis.

11. The apparatus of claim 10, the controller to further control a rotational offset, a rotational speed differential, or a combination thereof, between the first magnetron and the second magnetron.

12. A method comprising:
sputtering, with a sputtering magnetron, a target material from a target onto a substrate; and
altering, during the sputtering, a magnetic field profile of the sputtering magnetron.

13. The method of claim 12, altering the magnetic field profile of the sputtering magnetron further comprising:
moving the sputtering magnetron with respect to the target.

14. The method of claim 13, moving the magnetron with respect to the target further comprising:
rotating the magnetron about an axis.

15. The method of claim 14, moving the magnetron with respect to the target further comprising:
displacing the magnetron along the axis.

16. The method of claim 12 further comprising:
sputtering, with another sputtering magnetron, a target material from another target onto the substrate; and
altering, during the sputtering, a magnetic field profile of the other sputtering magnetron.

17. The method of claim 16 further comprising:
altering a rotational offset, a rotational speed differential, or a combination thereof, between the magnetron and the other magnetron.

18. The method of claim 12 further comprising:
sputtering, with another sputtering magnetron, a target material from another target onto another substrate; and
altering, during the sputtering, a magnetic field profile of the other sputtering magnetron.

19. The method of claim 18 further comprising:
altering a rotational offset, a rotational speed differential, or a combination thereof, between the magnetron and the other magnetron.
